(19) United States
(12) Patent Application Publication
(10) Pub. No.: US 2024/0387546 A1
(43) Pub. Date: Nov. 21, 2024

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: PO-YING CHANG, YUNLIN COUNTY (TW); WEN-LANG WU, TAICHUNG CITY (TW); CHANG-TAI LEE, NANTOU COUNTY (TW); LI-CHUNG KUO, TAICHUNG CITY (TW); YUN-HAN LIN, TAICHUNG CITY (TW); CHEN-CHUAN YANG, TAICHUNG CITY (TW)

(21) Appl. No.: 18/319,673

(22) Filed: May 18, 2023

(51) Int. Cl. H01L 27/092; H01L 21/8238; H01L 29/49; H01L 29/66; H01L 29/78

(52) U.S. Cl. CPC H01L 27/0924; H01L 21/823821; H01L 29/4958; H01L 29/66795; H01L 29/7851

(57) ABSTRACT

A semiconductor structure includes a first transistor and a second transistor. The first transistor includes a first fin structure and a first metal gate over the first fin structure. The first metal gate includes a first work function metal layer and a first gap-filling metal layer. The second transistor includes a second fin structure and a second metal gate over the second fin structure. The second metal gate includes a second work function metal layer and a second gap-filling metal layer. The first metal gate and the second metal gate provide a same work function. A width of the first metal gate is equal to a width of the second metal gate. A width of a top surface of the first gap-filling metal layer is greater than a width of a top surface of the second gap-filling metal layer.

### BACKGROUND

The semiconductor integrated circuit (IC) industry has experienced rapid growth. In the course of IC evolution, functional density (i.e., the number of interconnected devices per chip area) has generally increased while geometry size (i.e., the size of the smallest component (or line) that can be created using a fabrication process) has decreased. This scaling down process generally provides benefits by increasing production efficiency and lowering associated costs. Such scaling down has also increased the complexity of processing and manufacturing ICs, and for these advances to be realized, similar developments in IC manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor structure according to aspects of the present disclosure.

FIG. 2 shows perspective views illustrating portions of a semiconductor structure according to aspects of the present disclosure in one or more embodiments.

FIGS. 3 to 12 show cross-sectional views taken along lines X1-X1′ and X2-X2′ of FIG. 2, respectively at various stages in the method for forming the semiconductor structure according to aspects of the present disclosure.

FIG. 13 shows a cross-sectional view taken along a line X3-X3′ of FIG. 2.

FIGS. 14 to 20 show cross-sectional views respectively at various stages in the method for forming a semiconductor structure according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

As device geometry is reduced, parasitic resistance has increased. The parasitic resistance may degrade device performance by lowering an operation frequency of transistors. Such effect has become more evident in fin field-effect transistor (FinFET) devices than in planar devices and has affected transistors for radio frequency (RF) devices more adversely than transistors for logic devices. Therefore, how to reduce resistance of RF devices (i.e., RF FinFET devices) while maintaining high overall device density in an integrated circuit is an object of the present disclosure.

According to one embodiment of the present disclosure, a semiconductor structure including an RF device and a logic device is provided. In some embodiments, both the RF device and the logic device can be planar devices or non-planar devices. In some embodiments, the non-planar RF device and the non-planar logic device are FinFET devices. In some embodiments, the FinFET devices may be GAA devices, nanosheet devices, Omega-gate (a-gate) devices, Pi-gate (H-gate) devices, dual-gate devices, or tri-gate devices. The RF device and the logic device respectively include a metal gate. In some embodiments, a width of the metal gate of the RF device is equal to a width of the metal gate of the logic device. However, a width of a gap-filling metal in the metal gate of the RF device is greater than a width of a gap-filling metal in the metal gate of the logic device. In such embodiments, a volume of the gap-filling metal of the RF device is increased, and thus parasitic resistance of the RF device is reduced.

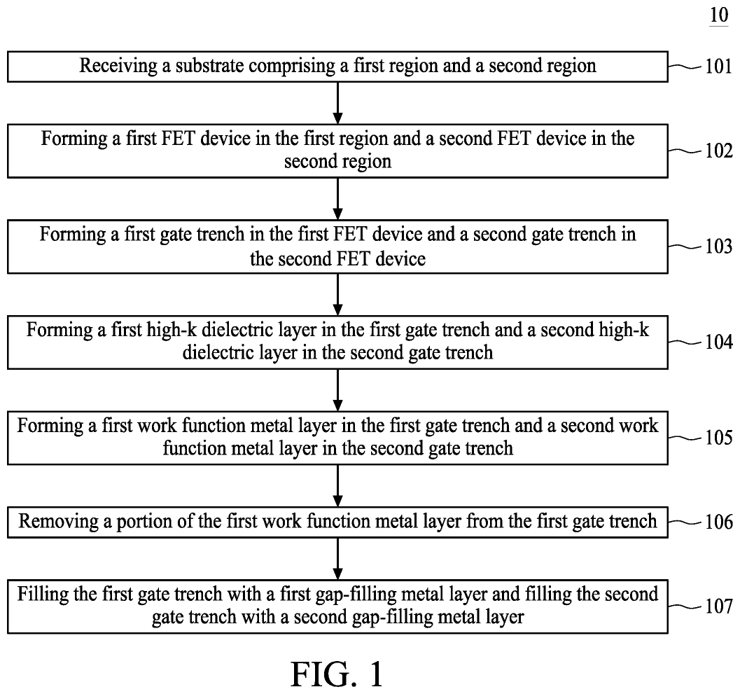

FIG. 1 is a flowchart representing a method 10 for forming a semiconductor structure according to aspects of the present disclosure. The semiconductor structure includes at least an RF device and a logic device. The RF device may perform power amplification, splitting, and/or combining; the logic device may perform input/output (I/O) functions and logic functions including AND, OR, NOR, and inverters, as well as other functions. In some embodiments, the RF device operates at a frequency about many times higher than a frequency of the logic device. For example, the RF device may operate at a frequency in a range from 3 GHz to 300 GHz, such as from 20 GHz to 300 GHz, while the logic device may operate at a frequency below 10 GHz. Further, the RF device and the logic device may be in separate regions of an IC or may be disposed in a common region of an IC.

In some embodiments, the method for forming the semiconductor structure 10 includes a number of operations (101, 102, 103, 104, 105, 106 and 107). The method 10 will be further described according to one or more embodiments. It should be noted that the operations of the method 10 may be rearranged or otherwise modified within the scope of the various aspects. It should further be noted that additional processes may be provided before, during, and after the method 10, and that some other processes may be only briefly described herein.

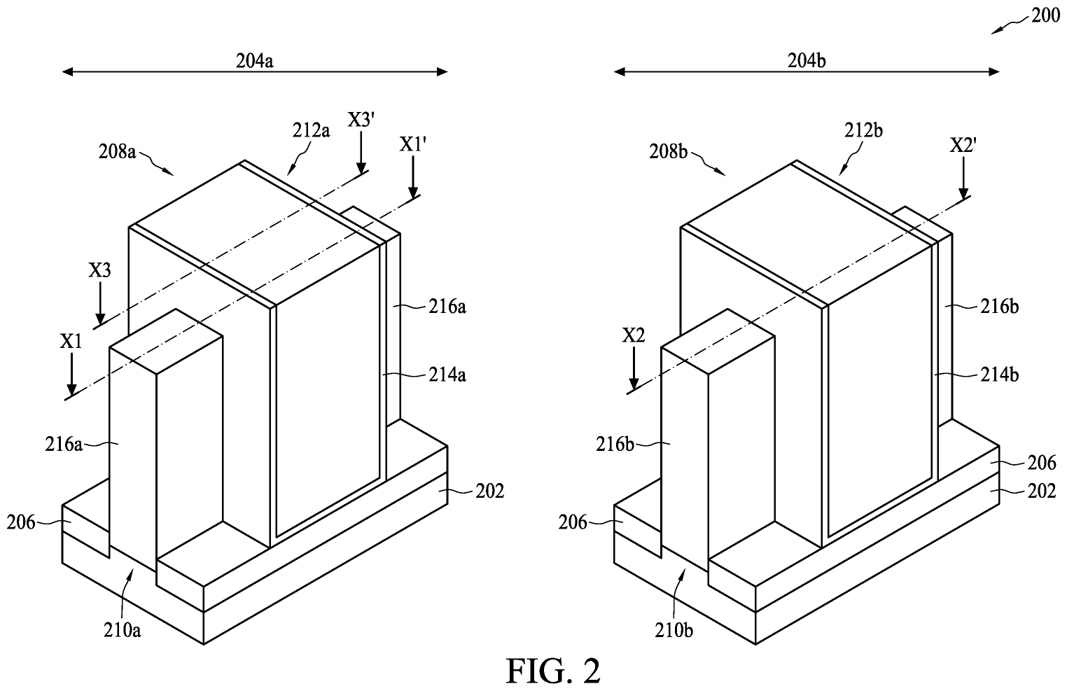

FIG. 2 shows perspective views illustrating portions of a semiconductor structure according to aspects of the present disclosure. In operation 101, a substrate 202 is received. In some embodiments, the substrate 202 may be a semiconductor substrate such as a silicon substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements, as is known in the art. For example, different doping profiles (e.g., n wells or p wells) may be formed on the substrate 202 in regions designed for different device types (e.g., n-type field-effect transistors (NFET), or p-type field-effect transistors (PFET)). The suitable doping may include ion implantation of dopants and/or diffusion processes.

As shown in FIG. 2, the substrate 202 may have a first region 204a and a second region 204b defined thereon. Further, the substrate 202 may include isolation structures, e.g., shallow trench isolation (STI) structures 206 interposing the first and second regions 204a and 204b. The first and second regions 204a and 204b are defined for accommodating different devices.

In operation 102, a first FET device 208a is formed in the first region 204a, and a second FET device 208b is formed in the second region 204b. In some embodiments, the first FET device 208a is an RF transistor while the second FET device 208b is a logic transistor, but the disclosure is not limited thereto. Further, the first FET device 208a is an n-type RF transistor, and the second FET device 208b is an n-type logic transistor. In other embodiments, the first FET device 208a may be a memory device while the second FET device 208b may be another type of device.

In some embodiments, the first FET device 208a includes a fin structure 210a, a sacrificial gate 212a, a spacer 214a and a source/drain 216a. The second FET device 208b includes a fin structure 210b, a sacrificial gate 212b, a spacer 214b and a source/drain 216b. A portion of the fin structure 210a covered by the sacrificial gate 212a serves as a channel region, and a portion of the fin structure 210b covered by the sacrificial gate 212b serves as a channel region. “Source/drain” may refer to a source or a drain, individually or collectively depending upon the context. In some embodiments, a width of the fin structure 210a and a width of the fin structure 210b are equal, but the disclosure is not limited thereto.

In some embodiments, the sacrificial gates 212a and 212b may respectively include a dielectric layer and a sacrificial semiconductor layer. In some embodiments, the sacrificial semiconductor layers are made of polysilicon, but the disclosure is not limited thereto. In some embodiments, the spacers 214a and 214b can be formed over sidewalls of the sacrificial gates 212a and 212b. In some embodiments, the spacers 214a and 214b are made of silicon nitride (SiN), silicon carbide (SiC), silicon oxide (SiO), silicon oxynitride (SiON), silicon carbide or any other suitable material, but the disclosure is not limited thereto. In some embodiments, the spacers 214a and 214b are formed by deposition and etch-back operations.

As shown in FIG. 2, in some embodiments, the source/drain 216a is formed over the fin structure 210a at two opposite sides of the sacrificial gate 212a. Similarly, the source/drain 216b is formed over the fin structure 210b at two opposite sides of the sacrificial gate 212b. In some embodiments, heights of the source/drain 216a and the source/drain 216b may be greater than heights of the fin structures 210a and 210b. In some embodiments, the source/drain 216a and the source/drain 216b may be formed by forming recesses in the fin structures 210a and 210b and growing a strained material in the recesses by an epitaxial (epi) process. In addition, a lattice constant of the strained material may be different from a lattice constant of the fin structures 210a and 210b. Accordingly, the source/drain 216a and the source/drain 216b may serve as stressors that improve carrier mobility. In some embodiments, the source/drain 216a and the source/drain 216b may both include n-type dopants, but the disclosure is not limited thereto.

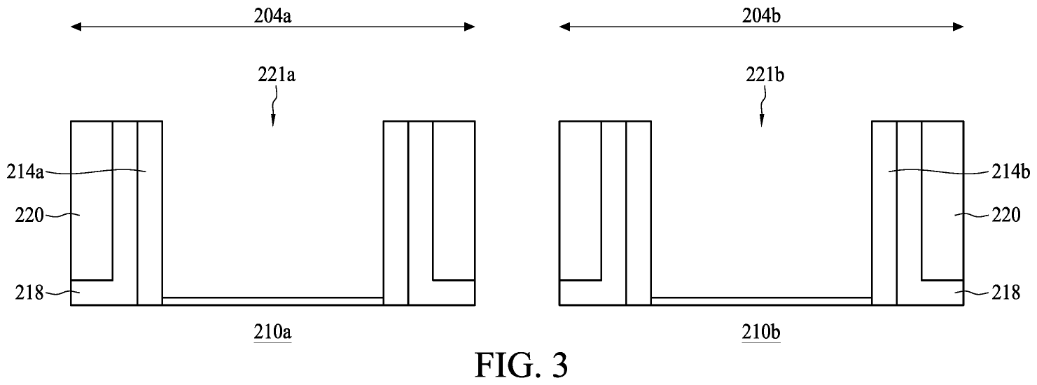

Please refer to FIG. 3, which shows cross-sectional views taken along lines X1-X1′ and X2-X2′ of FIG. 2, respectively. In some embodiments, after the forming of the source/drain 216a and the source/drain 216b, a contact etch stop layer (CESL) 218 may be formed to cover the sacrificial gates 212a and 212b over the substrate 202. In some embodiments, the CESL 218 can include silicon nitride, silicon oxynitride, and/or other applicable materials. Subsequently, an inter-layer dielectric (ILD) structure 220 may be formed on the CESL 218 in accordance with some embodiments. The ILD structure 220 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), or polyimide. Next, a polishing process is performed on the ILD structure 220 and the CESL 218 to expose top surfaces of the sacrificial gates 212a and 212b. In some embodiments, the ILD structure 220 and the CESL 218 are planarized by a chemical mechanical polishing (CMP) process until the top surfaces of the sacrificial gates 212a and 212b are exposed.

In operation 103, a gate trench 221a is formed in the first FET device 208a, and a gate trench 221b is formed in the second FET device 208b. In some embodiments, a width of the gate trench 221a is equal to a width of the gate trench 221b, but the disclosure is not limited thereto. In some embodiments, the sacrificial semiconductor layer is removed. In some embodiments, the dielectric layer may be removed for forming an interfacial layer (IL). In some embodiments, the dielectric layer may be left in the gate trench, though not shown. It should be noted that the removal of the dielectric layer may be performed depending on different process or product requirements. Accordingly, the fin structure 210a is exposed through the gate trench 221a, and the fin structure 210b is exposed through the gate trench 221b, as shown in FIG. 3.

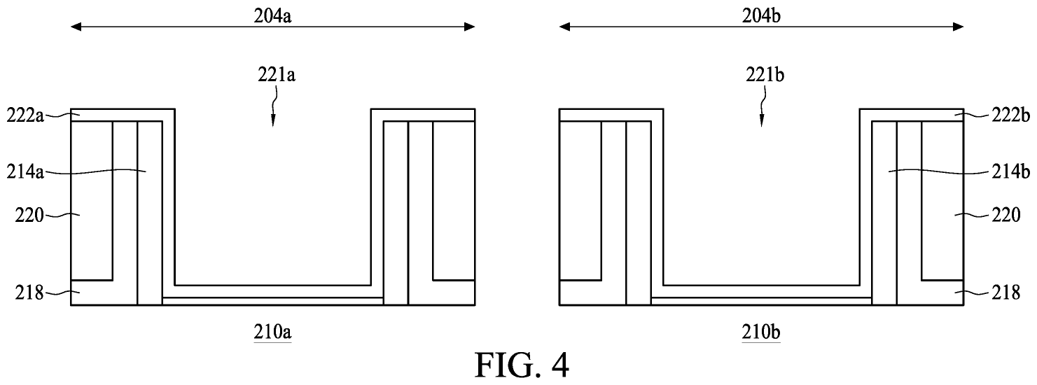

Referring to FIG. 4, in some embodiments, in operation 104, a high-k dielectric layer 222a is formed in the gate trench 221a, and a high-k dielectric layer 222b is formed in the gate trench 221b. A thickness of the high-k dielectric layer 222a and a thickness of the high-k dielectric layer 222b are similar. In some embodiments, an IL layer may be formed prior to the forming of the high-k dielectric layers 222a and 222b, though not shown. The IL layer may include an oxide-containing material such as SiO or SiON. In some embodiments, the IL layer covers portions of the fin structures 210a and 210b exposed in the gate trenches 221a and 221b. The high-k dielectric layers 222a and 222b may be simultaneously formed on the IL layer and conformally formed in the gate trenches 221a and 221b. Accordingly, the high-k dielectric layer 222a covers at least sidewalls of the gate trench 221a, and the high-k dielectric layer 222b covers at least sidewalls of the gate trench 221b. In some embodiments, the high-k dielectric layers 222a and 222b include a high-k dielectric material having a high dielectric constant, for example, a dielectric constant greater than that of thermal silicon oxide (\tilde{ }3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or combinations thereof.

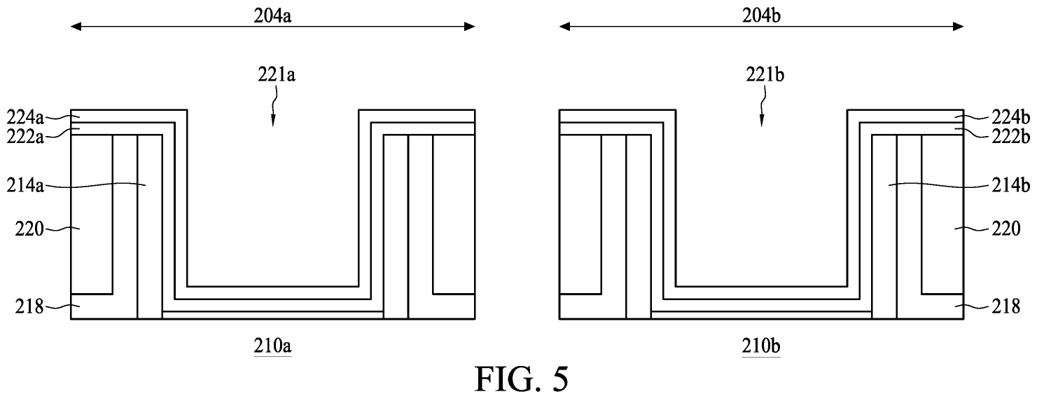

Referring to FIG. 5, in some embodiments, in operation 105, the method 10 includes forming a work function metal layer in the gate trench 221a and a work function metal layer in the gate trench 221b. In some embodiments, the operation 105 further includes forming other layers prior to and after the forming of the work function metal layers. For example, a metal layer 224a may be formed in the gate trench 221a and a metal layer 224b may be formed in the gate trench 221b. Additionally, the metal layer 224a is in contact with the high-k dielectric layer 222a, and the metal layer 224b is in contact with the high-k dielectric layer 222b. In some embodiments, the metal layers 224a and 224b include a same material such as, for example but not limited thereto, titanium nitride (TiN). A thickness of the metal layer 224a may be equal to a thickness of the metal layer 224b, but the disclosure is not limited thereto. In some embodiments, the metal layers 224a and 224b serve as a buffer layer. In other embodiments, the metal layers 224a and 224b serve as a barrier layer. Materials and thicknesses of the metal layers 224a and 224b may be selected depending functions that the metal layers 224a and 224b provide, and therefore such details are omitted for brevity.

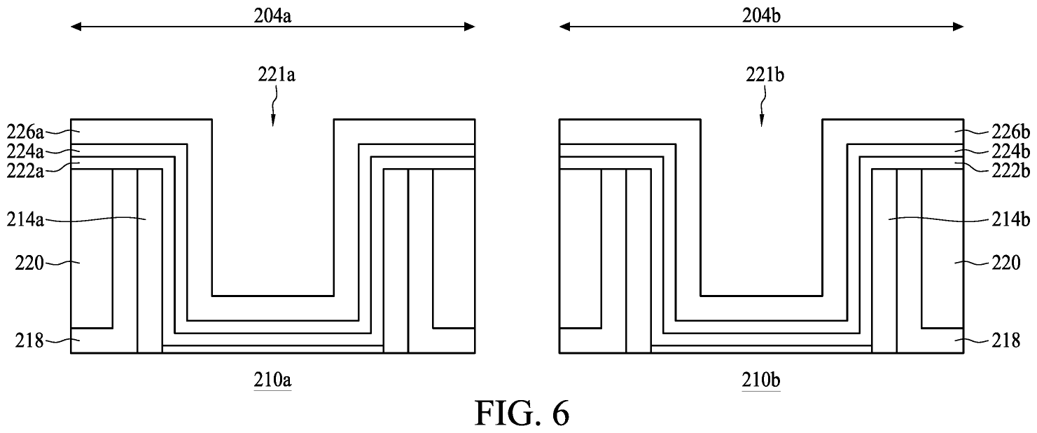

Referring to FIG. 6, in some embodiments, a work function metal layer 226a is formed over the metal layer 224a, and a work function metal layer 226b is formed over the metal layer 224b. In some embodiments, the work function metal layer 226a and the work function metal layer 226b may include a same material. For example, when both the first and second FET devices 208a and 208b are n-type devices, the work function metal layers 226a and 226b may include titanium (Ti), aluminum (Al), titanium aluminum (TiAl), tantalum carbide (TiC), tantalum carbide nitride (TiCN), tantalum silicon nitride (TaSiN), or combinations thereof. In some alternative embodiments, when both the first and second FET devices 208a and 208b are p-type devices, the work function metal layers 226a and 226b may include TiN, TaN, ruthenium (Ru), molybdenum (Mo), tungsten (W), platinum (Pt), TiAl, or a combination thereof. The work function metal layers 226a and 226b may be formed by CVD, PVD and/or other suitable process. In some embodiments, thicknesses of the work function metal layers 226a and 226b are greater than thicknesses of the buffer layers 224a and 224b.

In some embodiments, an intervening metal layer (not shown) can be formed prior to the forming of the work function metal layers 226a and 226b, though not shown. In such embodiments, the intervening metal layer is disposed between the metal layer 224a and the work function metal layer 226a, and between the metal layer 224b and the work function metal layer 226b. In some embodiments, the intervening metal layer may include materials different from those of the work function metal layers 226a and 226b. For example, when the work function metal layers 226a and 226b include TiAl, the intervening metal layer may include TiN, but the disclosure is not limited thereto. In some embodiments, the intervening metal layer and the metal layers 224a and 224b may include a same material. In some alternative embodiments, the intervening metal layer and the metal layers 224a and 224b may include different materials. In some embodiments, a thickness of the intervening metal layer may be equal to a thickness of the metal layers 224a and 224b. In other embodiments, the thickness of the intervening metal layer may be two to five times the thickness of the metal layers 224a and 224b. In some embodiments, the intervening metal layer may be a single-layered structure. In other embodiments, the intervening metal layer may be a multilayered structure. In such embodiments, the intervening metal layer may include TiN and TaN, but the disclosure is not limited thereto.

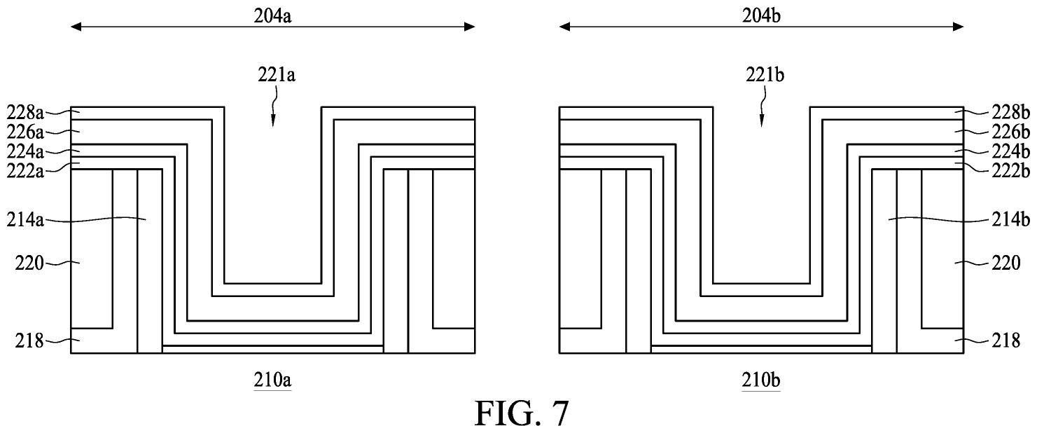

Referring to FIG. 7, in some embodiments, another metal layer 228a is formed over the work function metal layer 226a, and another metal layer 228b is formed over the work function metal layer 226b. In some embodiments, the metal layers 228a and 228b include TiN, but the disclosure is not limited thereto. Thicknesses of the metal layers 228a and 228b are less than thicknesses of the work function metal layers 226a and 226b.

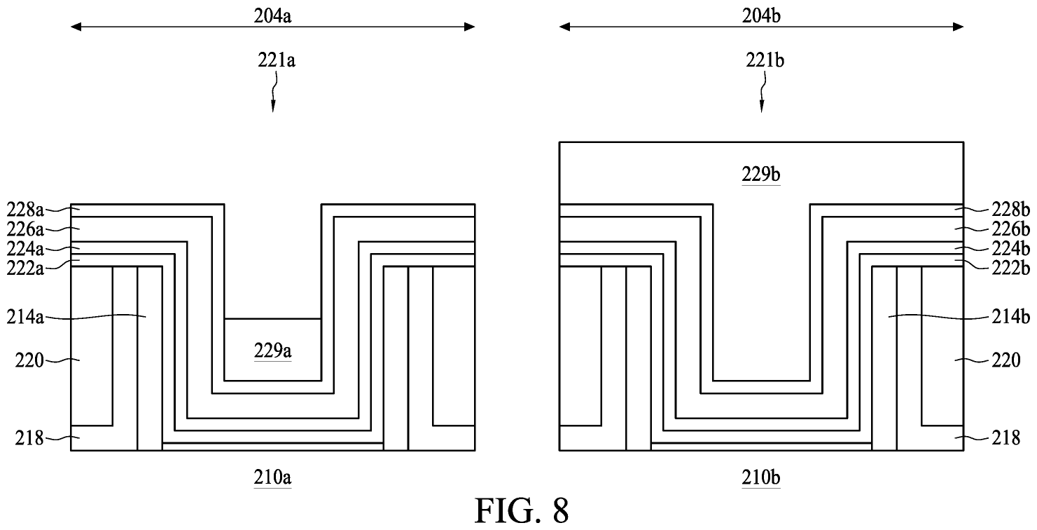

In operation 106, a portion of the work function metal layer 226a is removed from the gate trench 221a. In some embodiments, operation 106 may include further processes. For example, a sacrificial layer 229a may be formed in the gate trench 221a and a sacrificial layer 229b may be formed in the gate trench 221b. In some embodiments, the sacrificial layers 229a and 229b include a same material, such as a photoresist, but the disclosure is not limited thereto. In some embodiments, a sacrificial material is formed over the substrate 202 and fills the gate trenches 221a and 221b. Subsequently, portions of the sacrificial material are removed from the first region 204a to form the sacrificial layer 229a in the first region and the sacrificial layer 229b in the second region 204b. As shown in FIG. 8, a top surface of the sacrificial layer 229a is lower than an opening of the gate trench 221a. That is, portions of the metal layer 228a are exposed through the gate trench 221a while other portions of the metal layer 228a are covered by the sacrificial layer 229a. In contrast, the sacrificial layer 229b in the second region 204b covers the metal layer 228b entirely.

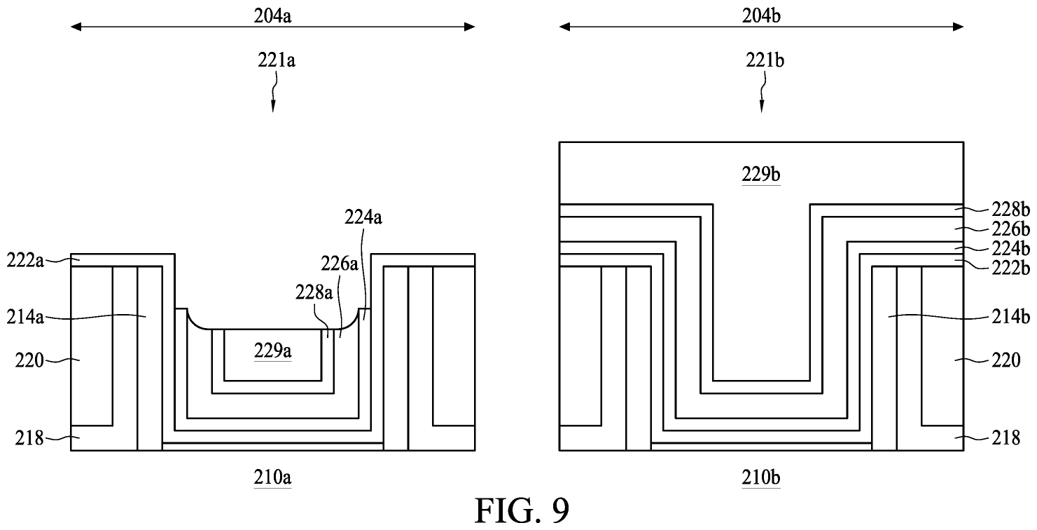

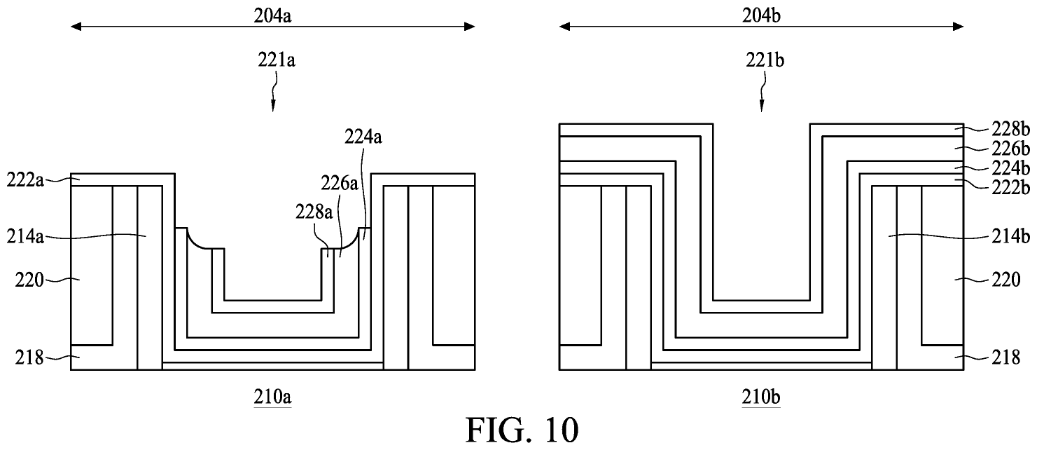

Referring to FIG. 9, in operation 106, portions of the metal layer 228a, portions of the work function metal layer 226a and portions of the metal layer 224a are removed from the gate trench 221a and from the first region 204a. Subsequently, in some embodiments, topmost portions of the metal layer 228a, topmost portions of the work function metal layer 226a and topmost portions of the metal layer 224a are lower than the opening of the gate trench 221a. In some embodiments, the high-k dielectric layer 222a serves as an etch stop layer, and thus the ILD structure 220 and the CESL 218 may be protected by the high-k dielectric layer 222a during the removing of the portions of the metal layer 228a, the work function metal layer 226a and the metal layer 224a. In contrast to such removal, in the second regions 204b, the metal layer 228b, the work function metal layer 226b and the metal layer 224b are protected by the sacrificial layer 229b and thus remain intact. Subsequently, the sacrificial layers 229a and 229b are removed, as shown in FIG. 10.

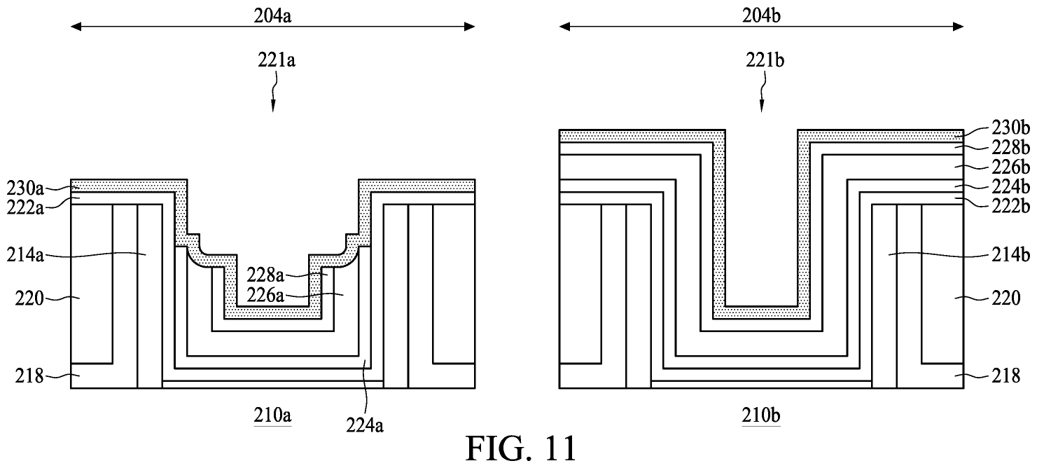

In operation 107, the gate trenches 221a and 221b are filled with a gap-filling metal layer. In some embodiments, the operation 107 includes additional processes. For example, an intervening metal layer 230a is formed in the gate trench 221a, and an intervening metal layer 230b is formed in the gate trench 221b, as shown in FIG. 11. In some embodiments, the intervening metal layers 230a and 230b include a same material, such as TiN, but the disclosure is not limited thereto. In some embodiments, the intervening metal layers 230a and 230b include a same thickness, but the disclosure is not limited thereto. The intervening metal layers 230a and 230b may serve as a glue layer for improving attachment between the metal layers 228a and 228b and a to-be-formed layer.

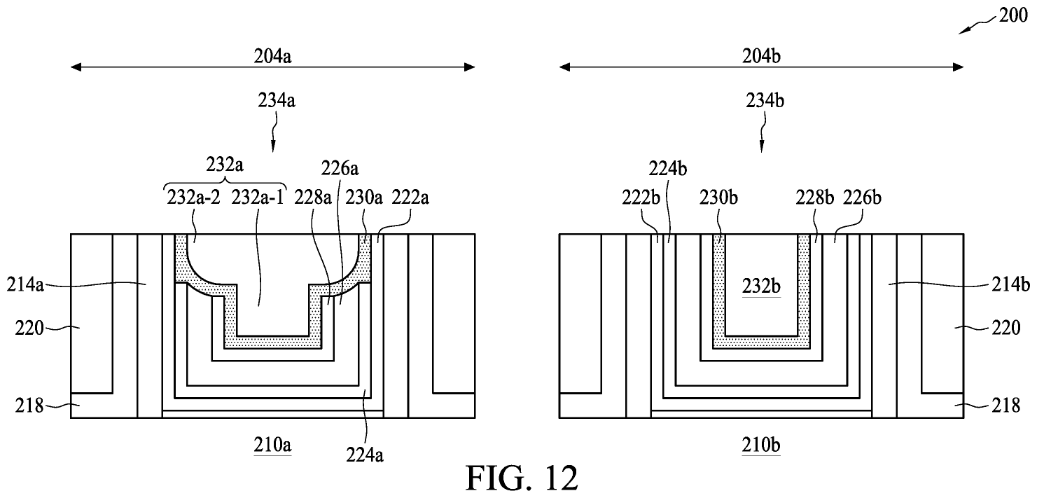

Referring to FIG. 12, a gap-filling metal layer 232a is formed to fill the gate trench 221a, and a gap-filling metal layer 232b is formed to fill the gate trench 221b. The gap-filling metal layers 232a and 232b may include metal materials having low resistance, such as aluminum (Al), tungsten (W), copper (Cu), and/or other suitable materials, and may be formed by CVD, PVC, plating and/or other suitable processes. Further, a CMP is performed to remove superfluous metals, such that a top surface of the ILD structure 220, a top surface of the gap-filling metal layer 232a, and a top surface of the gap-filling metal layer 232b are aligned (i.e., coplanar) with each other, as shown in FIG. 12. Accordingly, a metal gate 234a is obtained in the first region 204a, and a metal gate 234b is obtained in the second region 204b. As shown in FIG. 12, the metal gate 234a includes the high-k dielectric layer 222a, the metal layer 224a, the work function metal layer 226a, the metal layer 228a, the intervening metal layer 230a, and the gap-filling metal layer 232a, and the metal gate 234b includes the high-k dielectric layer 222b, the metal layer 224b, the work function metal layer 226b, the metal layer 228b, the intervening metal layer 230b and the gap-filling metal layer 232b. In some embodiments, further processes, such as contact and via formation, interconnect processing, etc., may be performed subsequently to complete the fabrication of the metal gates 234a and 234b.

Referring to FIG. 12, accordingly, the semiconductor structure 200 is formed including the first FET device 208a (i.e., the RF transistor) having the metal gate 234a, and the second FET device 208b (i.e., the logic transistor) having the metal gate 234b. In some embodiments, the high-k dielectric layer 222a of the metal gate 234a and the high-k dielectric layer 222b of the metal gate 234b include a same material and a same thickness. In some embodiments, the work function metal layer 226a of the metal gate 234a and the work function metal layer 226b of the metal gate 234b include a same material and a same thickness. In some embodiments, the gap-filling metal layer 232a of the metal gate 234a and the gap-filling metal layer 232b of the metal gate 234b include a same material. The metal gate 234a and the metal gate 234b have a same work function due to having the same material. Further, a width of the metal gate 234a is equal to a width of the metal gate 234b.

Still referring to FIG. 12, in some embodiments, the metal gate 234a of the first FET device 208a and the metal gate 234b of the second FET device 208b have different configurations. In the metal gate 234b, topmost portions of the high-k dielectric layer 222b, topmost portions of the metal layer 224b, topmost portions of the work function metal layer 226b, topmost portions of the metal layer 227b, topmost portions of the intervening metal layer 230b, and the top surface of the gap-filling metal layer 232b are aligned (i.e., coplanar) with each other. Further, the topmost portions and top surfaces of the above-mentioned layers, 222b, 224b, 226b, 228b, 230b and 232b, are aligned (i.e., coplanar) with the top surface of the ILD structure 220 over the substrate 202. Further, the gap-filling metal layer 232b has a consistent width. That is, a width of a bottom surface of the gap-filling metal layer 232b is equal to a width of the top surface of the gap-filling metal layer 232b. Accordingly, the gap-filling metal layer 232b may have an I-shaped configuration, but the disclosure is not limited thereto.

In contrast to the above configuration of the metal gate 234b, topmost portions of the high-k dielectric layer 222a, topmost portions of the intervening metal layer 230a and the top surface of the gap-filling metal layer 232a of the metal gate 234a of the first FET device 208a are aligned (i.e., coplanar) with the top surface of the ILD structure 220, while the topmost portions of the metal layer 224a, the topmost portions of the work function metal layer 226a and the topmost portions of the metal layer 228a are lower than the top surface of the ILD structure 220. Further, the intervening metal layer 230a is in contact with the topmost portions of the metal layer 224a, the topmost portions of the work function metal layer 226a, and the topmost portions of the metal layer 228a. As shown in FIG. 12, the gap-filling metal layer 232a has an inconsistent width. In some embodiments, the gap-filling metal layer 232a has a first portion 232a-1 and a second portion 232a-2 over the first portion 232a-1. A top surface of the second portion 232a-2 is aligned with the top surface of the ILD structure 220, and a bottom surface of the second portion 232a-2 is in contact with the intervening metal layer 230a. A width of the top surface of the gap-filling metal layer 232a is greater than a width of a bottom surface of the gap-filling metal layer 232a. In other words, a width of the second portion 232a-2 is greater than a width of the first portion 232a-1. Accordingly, the gap-filling metal layer 232a may have a T-shaped configuration, but the disclosure is not limited thereto. In some embodiments, the width of the second portion 232a-2 is greater than the width of the gap-filling metal layer 232b. In some embodiments, the width of the first portion 232a-1 is equal to the width of the gap-filling metal layer 232b, but the disclosure is not limited thereto. In other words, the width of the bottom surface of the gap-filling metal layer 232a is equal to the width of the bottom surface of the gap-filling metal layer 232b.

Additionally, the intervening metal layer 230b is entirely separated from the high-k dielectric layer 222b, while portions of the intervening metal layer 230a are in contact with the high-k dielectric layer 222a.

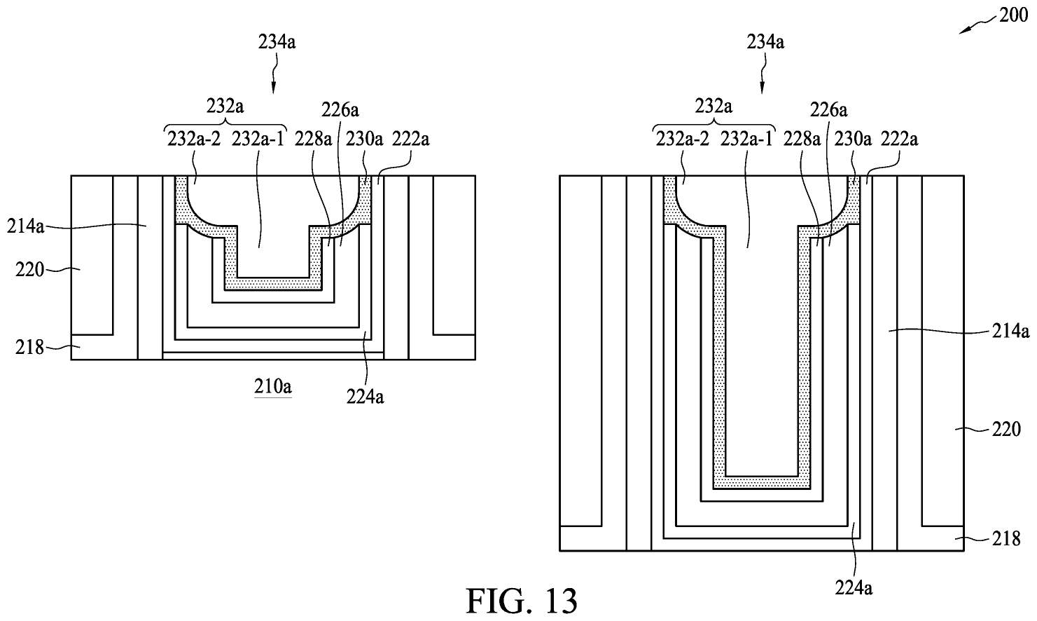

Please refer to FIGS. 12 and 13, where FIG. 13 is a cross-sectional view taken along line X3-X3′ of FIG. 2. The metal gate 234a is disposed not only over a portion of the fin structure 210a, but also over a portion of the isolation structure 206, as shown in FIG. 13. Comparing a volume of the gap-filling metal layer 232a and a volume of the gap-filling metal layer 232b, it can be seen that the volume of the gap-filling metal layer 232a is greater than the volume of the gap-filling metal layer 232b by between approximately 5% and approximately 30%. Accordingly, a resistance of the metal gate 234a is reduced and thus performance of the first FET device (i.e., the RF transistor) 208a is improved.

In some embodiments, a p-type FET device can be formed by the method 10, although not shown. The p-type FET device may have a metal gate having a configuration similar to that of the second device 208b. In such embodiments, the metal gate of the p-type FET device includes a high-k dielectric layer, a first work function metal layer over the high-k dielectric layer, a second work function metal layer over the first work function metal layer, an intervening metal layer and a gap-filling metal layer. The first work function metal layer provides work function for the p-type FET device, and may include a material same as those of the metal layers 224a and 224b. For example, the first work function metal layer includes TiN. The second work function metal layer includes material same as those of the work function metal layers 226a and 226b. For example, the second work function metal layer may include TiAl. The intervening metal layer include a material same as those of the intervening metal layers 230a and 230b, and the gap-filling metal layer includes a material same as those of the gap-filling metal layers 232a and 232b. In such embodiments, the gap-filling metal layer of the p-type FET device has an I-shaped configuration. Further, a width of a top surface of the gap-filling metal layer of the metal gate of the p-type FET device is less than the width of the top surface of the gap-filling metal layer 232a of the first device 208a (i.e., the RF transistor). Additionally, the width of the top surface of the gap-filling metal layer of the metal gate of the p-type FET device is equal to the width of the top surface of the gap-filling metal layer 232b of the second device 208b (i.e., the logic transistor).

According to the method 10 provided by the present disclosure, resistance of the metal gate 234a is reduced and performance of the RF device 208a is improved due to the T-shaped gap-filling metal layer 232a, while the operations for forming the RF transistor 208a and the logic transistor 208b maintain process stability. In other words, influence on the logic transistor 208b caused by the forming of the T-shaped gap-filling metal layer 232b of the RD transistor 208a is negligible. It is therefore concluded that the method 10 provided by the present disclosure is compatible with the operations for forming a semiconductor structure having the RF devices and the logic devices integrated together.

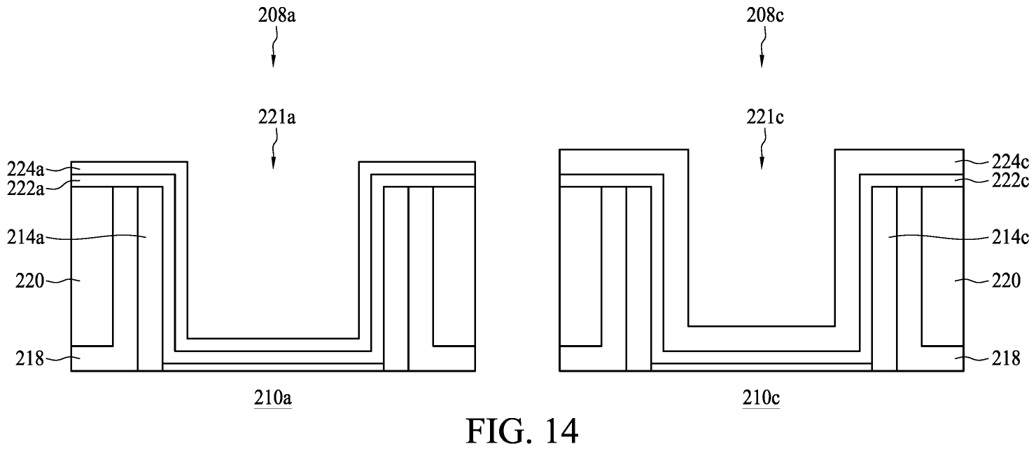

In some embodiments, the method 10 can be performed to form other devices. For example, while forming the first device 208a and the second device 208b having a same conductivity type (i.e., the n type), the method 10 can be performed to form p-type device at the same time. FIGS. 14 to 20 shows cross-sectional views of a semiconductor structure including an n-type FET device and a p-type FET device at various stages of the method 10 according to aspects of the present disclosure. It should be understood that same elements in FIGS. 2 to 12 and FIGS. 14 to 20 are depicted by same numerals, and can include same materials, and thus repeated descriptions may be omitted in the interest of brevity.

Referring to FIG. 14, in operation 101, a substrate is received, and the substrate may have different regions with STI structures interposing the regions for providing electrical isolation. The regions are defined for accommodating different devices. In operation 102, a first FET device 208a and a third FET device 208c are formed in the different regions. In some embodiments, both of the first and the third FET devices 208a and 208c are RF transistors, but the disclosure is not limited thereto. In some embodiments, the first and the third FET devices 208a and 208c may both be logic devices or memory devices. However, the first FET device 208a and the third FET device 208c are complementary to each other. For example, the first FET device 208a may be an n-type FET device, and the third FET device 208c may be a p-type FET device.

As mentioned above, the first FET device 208a includes a fin structure 210a, a sacrificial gate (not shown), a spacer 214a and a source/drain (not shown). Similarly, the third FET device 208c includes a fin structure 210c, a sacrificial gate (not shown), a spacer 214c and a source/drain (not shown). A portion of the fin structure 210a covered by the sacrificial gate serves as a channel region. In some embodiments, a width of the fin structure 210a and a width of the fin structure 210c are equal, but the disclosure is not limited thereto. In some embodiments, a CESL 218 is formed over the substrate. Subsequently, an ILD structure 220 is formed on the CESL 218. Next, a polishing process such as a CMP is performed on the ILD structure 220 and the CESL 218 to expose top surfaces of the sacrificial gates.

In operation 103, a gate trench 221a is formed in the first FET device 208a, and a gate trench 221c is formed in the third FET device 208c. In some embodiments, a width of the gate trench 221a is equal to a width of the gate trench 221c, but the disclosure is not limited thereto. As mentioned above, the sacrificial gates are removed. Accordingly, the fin structure 210a is exposed through the gate trench 221a, and the fin structure 210c is exposed through the gate trench 221c.

Still referring to FIG. 14, in some embodiments, in operation 104, the method 10 includes forming a high-k dielectric layer 222a in the gate trench 221a, and a high-k dielectric layer 222c in the gate trench 221c. A thickness of the high-k dielectric layer 222a and a thickness of the high-k dielectric layer 222c are similar. In some embodiments, an IL layer may be formed prior to the forming of the high-k dielectric layers 222a and 222c, though not shown.

Still referring to FIG. 14, in some embodiments, in operation 105, the method 10 includes forming a work function metal layer in the gate trench 221a and a work function metal layer in the gate trench 221c. In some embodiments, the operation 105 further includes forming other layers prior to and after the forming of the work function metal layers. For example, a metal layer 224a may be formed in the gate trench 221a, and the metal layer 224a is in contact with the high-k dielectric layer 222a. In some embodiments, a work function metal layer 224c is formed in the gate trench 221c, and the work function metal layer 224c is in contact with the high-k dielectric layer 222c. The work function metal layer 224c provides a work function for a p-type FET device 208c. In some embodiments, the metal layer 224a and the work function metal layer 224c include a same material such as, for example but not limited thereto, TiN. Further, a thickness of the metal layer 224a is less than a thickness of the work function metal layer 224c. The metal layer 224a serves as a buffer layer or a barrier layer. Materials and the thickness of the metal layer 224a may be selected depending on functions to be provided by that the metal layer 224a, and repeated descriptions are omitted for brevity.

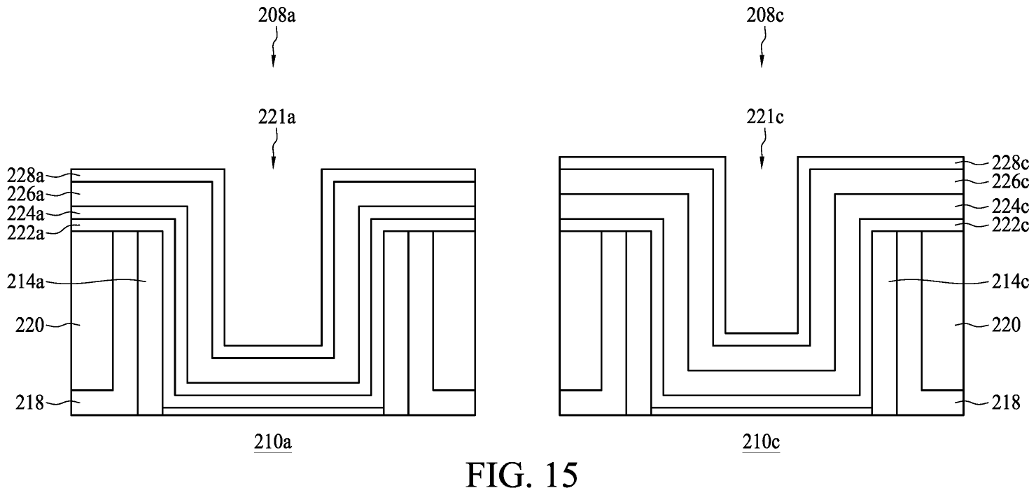

Referring to FIG. 15, in some embodiments, a work function metal layer 226a is formed over the metal layer 224a in the gate trench 221a. The work function metal layer 226a provides a work function for the n-type FET device 208a. Further, a metal layer 226c is formed over the work function metal layer 224c in the gate trench 221c. In some embodiments, the work function metal layer 226a and the metal layer 226c include a same material. For example, the work function metal layer 226a and the metal layer 226c both include TiAl. In some embodiments, a thickness of the work function metal layer 226a and a thickness of the metal layer 226c are equal, but the disclosure is not limited thereto.

Still referring to FIG. 15, in some embodiments, another metal layer 228a is formed over the work function metal layer 226a in the gate trench 221a, and another metal layer 228c is formed over the metal layer 226c in the gate trench 221c. In some embodiments, the metal layers 228a and 228c include TiN, but the disclosure is not limited thereto. Thicknesses of the metal layers 228a and 228c are less than the thicknesses of the work function metal layer 226a and the metal layer 226c. Further, the thickness of the metal layer 228a and the thickness of the metal layer 228c are equal.

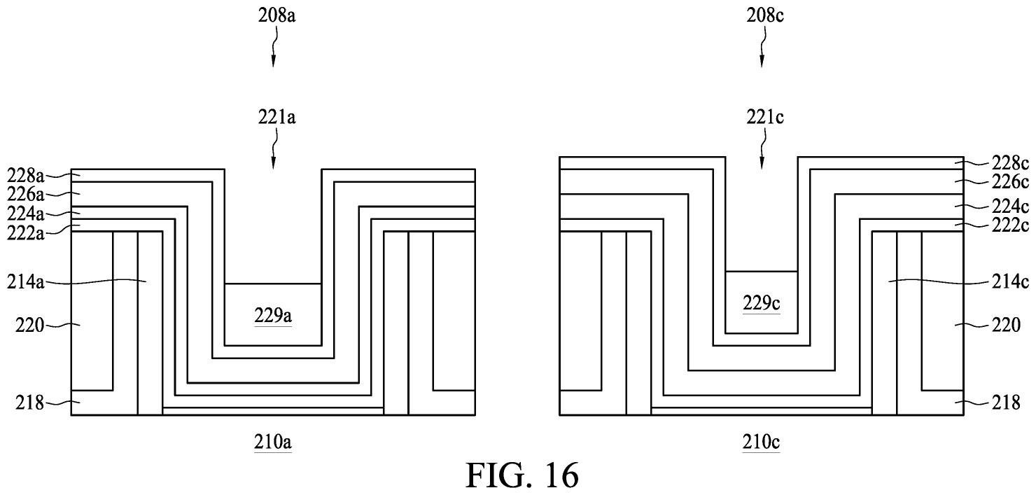

In operation 106, a portion of the work function metal layer 226a is removed from the gate trench 221a. In some embodiments, operation 106 may include further processes. For example, a portion of the work function metal layer 224c is removed from the gate trench 221c. In such embodiments, as shown in FIG. 16, a sacrificial layer 229a is formed in the gate trench 221a and a sacrificial layer 229c is formed in the gate trench 221c. In some embodiments, the sacrificial layers 229a and 229c include a same material, such as a photoresist, but the disclosure is not limited thereto. In some embodiments, a sacrificial material is formed over the substrate 202 and fills the gate trenches 221a and 221c. Subsequently, portions of the sacrificial material are removed to form the sacrificial layers 229a and 229c. As shown in FIG. 16, a top surface of the sacrificial layer 229a is lower than an opening of the gate trench 221a, and a top surface of the sacrificial layer 229c is lower than an opening of the gate trench 221c.

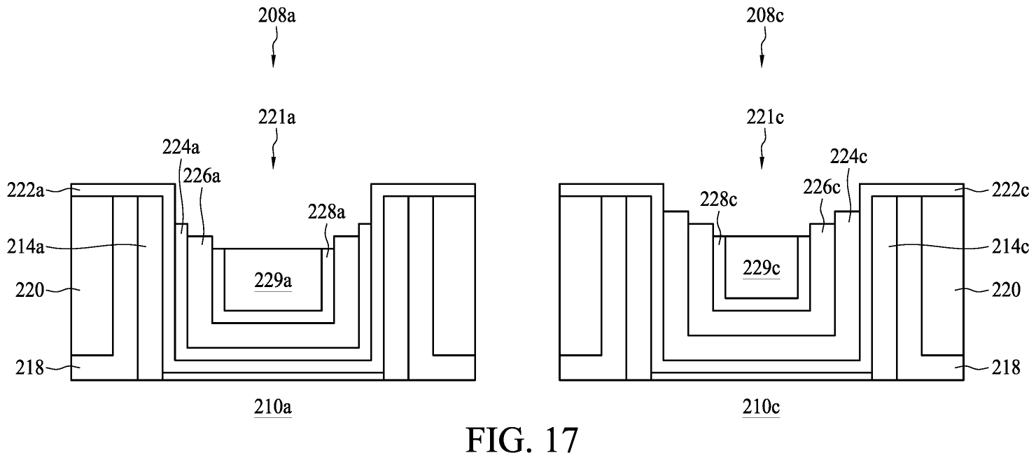

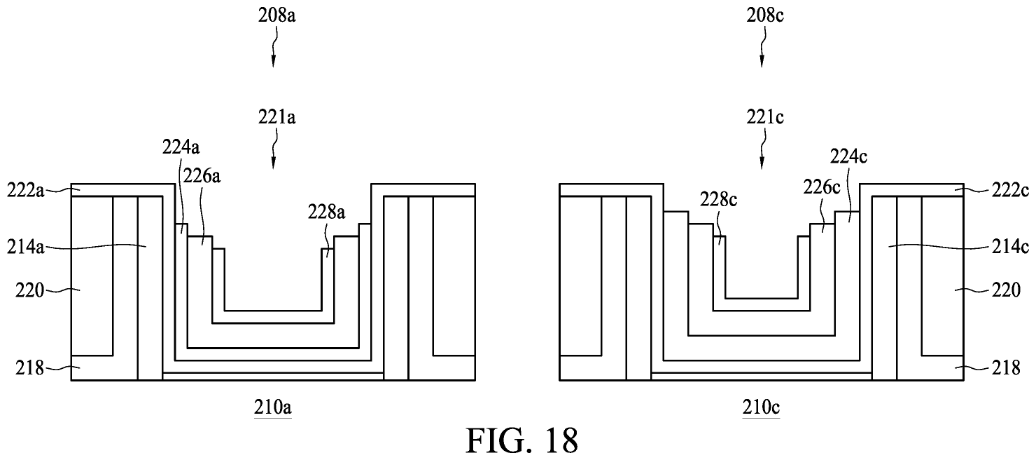

Referring to FIG. 17, in operation 106, portions of the metal layer 228a, portions of the work function metal layer 226a and portions of the metal layer 224a are removed from the gate trench 221a. Similarly, portions of the metal layer 228c, portions of the metal layer 226c, and portions of the work function metal layer 224c are removed from the gate trench 221c. Accordingly, topmost portions of the metal layer 228a, topmost portions of the work function metal layer 226a, and topmost portions of the metal layer 224a are lower than the opening of the gate trench 221a, and topmost portions of the metal layer 228c, topmost portions of the metal layer 226c and topmost portions of the work function metal layer 224c are lower than the opening of the gate trench 221c. In some embodiments, the high-k dielectric layers 222a and 222c serve as an etch stop layer, and thus the ILD structure 220 and the CESL 218 are protected by the high-k dielectric layers 222a and 222c. Referring to FIG. 18, the sacrificial layers 229a and 229c are then removed.

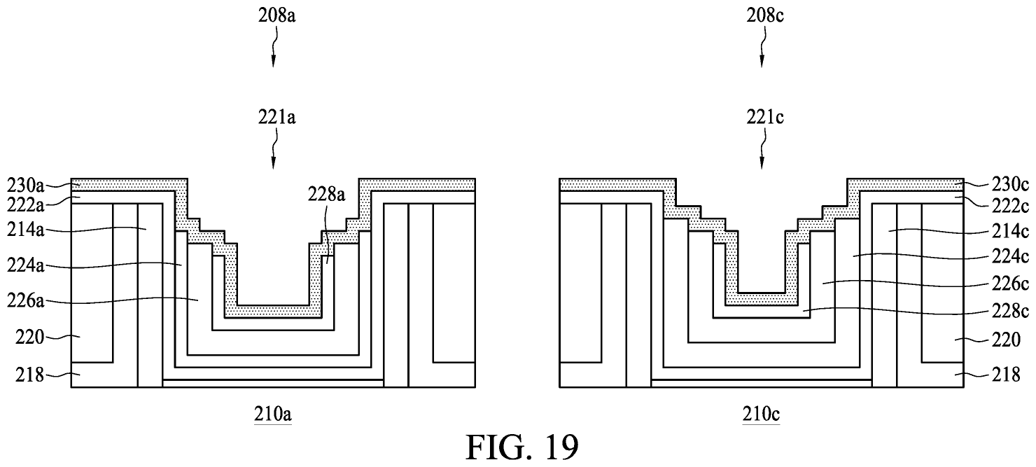

In operation 107, the gate trenches 221a and 221c are filled with a gap-filling metal layer. In some embodiments, the operation 107 includes further processes. For example, an intervening metal layer 230a is formed in the gate trench 221a, and an intervening metal layer 230c is formed in the gate trench 221c, as shown in FIG. 19. In some embodiments, the intervening metal layers 230a and 230c include a same material, such as TiN, but the disclosure is not limited thereto. In some embodiments, the intervening metal layers 230a and 230c include a same thickness, but the disclosure is not limited thereto. As mentioned above, the intervening metal layers 230a and 230c serve as glue layers for improving attachment between the metal layers 228a and 228c and layers to be subsequently formed.

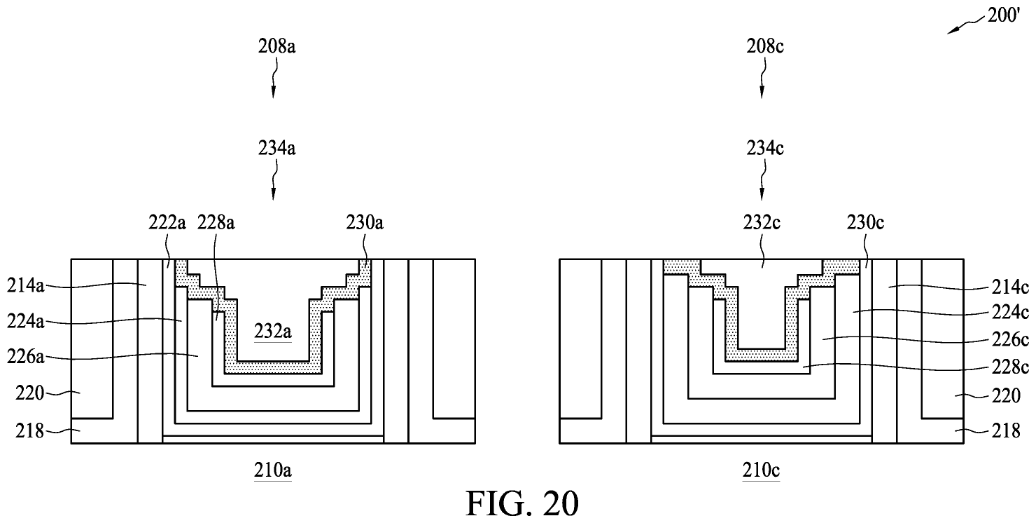

Referring to FIG. 20, a gap-filling metal layer 232a is formed to fill the gate trench 221a, and a gap-filling metal layer 232c is formed to fill the gate trench 221c. The gap-filling metal layers 232a and 232c may include tungsten. Further, a CMP is performed to remove superfluous materials, such that a top surface of the ILD structure 220, a top surface of the gap-filling metal layer 232a, and a top surface of the gap-filling metal layer 232c are aligned (i.e., coplanar) with each other, as shown in FIG. 20. Accordingly, a metal gate 234a is obtained for the n-type FET device 208a, and a metal gate 234c is obtained for the p-type FET device 208c. As shown in FIG. 20, the metal gate 234a includes the high-k dielectric layer 222a, the metal layer 224a, the work function metal layer 226a, the metal layer 228a, the intervening metal layer 230a, and the gap-filling metal layer 232a, and the metal gate 234c includes the high-k dielectric layer 222c, the work function metal layer 224c, the metal layer 226c, the metal layer 228c, the intervening metal layer 230c and the gap-filling metal layer 232c. In some embodiments, further processes, such as contact and via formation, interconnect processing, etc., may be performed subsequently to complete the fabrication of the metal gates 234a and 234c.

Referring to FIG. 20, accordingly, a semiconductor structure 200′ including the n-type FET device 208a and the p-type FET device 208c is obtained. In such embodiments, the work function metal layer 226a of the n-type FET device 208a is different from the work function metal layer 224c of the p-type FET device 208c. As mentioned above, the topmost portions of the high-k dielectric layer 222a, the topmost portions of the intervening metal layer 230a, and a top surface of the gap-filling metal layer 232a of the metal gate 234a of the n-type FET device 208a are aligned (i.e., coplanar) with the top surface of the ILD structure 220, while the topmost portions of the metal layer 224a, the topmost portions of the work function metal layer 226a and the topmost portions of the metal layer 228a are lower than the top surface of the ILD structure 220. In addition, the topmost portions of the high-k dielectric layer 222c, the topmost portions of the intervening metal layer 230c, and the top surface of the gap-filling metal layer 232c of the metal gate 234c of the p-type FET device 208c are aligned (i.e., coplanar) with the top surface of the ILD structure 220, while the topmost portions of the work function metal layer 224c, the topmost portions of the metal layer 226c and the topmost portions of the metal layer 228c are lower than the top surface of the ILD structure 220.

Further, the intervening metal layer 230a is in contact with the topmost portions of the metal layer 224a, the topmost portions of the work function metal layer 226a, and the topmost portions of the metal layer 228a. The intervening metal layer 230c is in contact with the topmost portions of the work function metal layer 224c, the topmost portions of the metal layer 226c, and the topmost portions of the metal layer 228c. Therefore, both of the gap-filling metal layers 232a and 232c have inconsistent widths. In some embodiments, a width of an upper portion of the gap-filling metal layer 232a is greater than a width of a lower portion of the gap-filling metal layer 232a. A width of an upper portion of the gap-filling metal layer 232c is greater than a width of the lower portion of the gap-filling metal layer 232c. Accordingly, both of the gap-filling metal layers 232a and 232c have a T-shaped configuration, but the disclosure is not limited thereto. In some embodiments, the width of the upper portion of the gap-filling metal layer 232a is greater than the width of the upper portion of the gap-filling metal layer 232c. In some embodiments, the width of the lower portion of the gap-filling metal layer 232a is greater than the width of the lower portion of the gap-filling metal layer 232c, but the disclosure is not limited thereto.

Additionally, a portion of the intervening metal layer 230a is in contact with the high-k dielectric layer 222a, and a portion of the intervening metal layer 230c is in contact with the high-k dielectric layer 222c.

According to the method provided by the present disclosure, resistances of the metal gates 234a and 234c are reduced and performances of the n-type FET device 208a and the p-type FET device 208c are improved due to the T-shaped gap-filling metal layers 232a and 232c. In some embodiments, the method 10 can be performed to form an RF transistor and/or a logic transistor. It is therefore concluded that the method 10 provided by the present disclosure is compatible with the operations for forming a semiconductor structure.

In summary, a semiconductor structure including an RF device and a logic device is provided according to the present disclosure. The RF device and the logic device respectively include a metal gate. In some embodiments, a width of the metal gate of the RF device is equal to a width of the metal gate of the logic device. However, a width of a gap-filling metal in the metal gate of the RF device is greater than a width of a gap-filling metal in the metal gate of the logic device. In such embodiments, a volume of the gap-filling metal of the RF device is increased, and thus parasitic resistance of the RF device is reduced.

According to one embodiment of the present disclosure, a semiconductor structure is provided. The semiconductor structure includes a first transistor and a second transistor. The first transistor includes a first fin structure and a first metal gate over the first fin structure. The first metal gate includes a first work function metal layer and a first gap-filling metal layer. The second transistor includes a second fin structure and a second metal gate over the second fin structure. The second metal gate includes a second work function metal layer and a second gap-filling metal layer. The first metal gate and the second metal gate provide a same work function. A width of the first metal gate is equal to a width of the second metal gate. A width of a top surface of the first gap-filling metal layer is greater than a width of a top surface of the second gap-filling metal layer.

According to one embodiment of the present disclosure, a semiconductor structure is provided. The semiconductor structure includes an RF device and a logic device. The RF device include a first metal gate, and the first metal gate includes a first gap-filling metal layer. A width of a top surface of the first gap-filling metal layer is greater than a width of a bottom surface of the first gap-filling metal layer. The logic device includes a second metal gate, and the second metal gate includes a second gap-filling metal layer. The first metal gate and the second metal gate provide a same work function. A width of the first metal gate is equal to a width of the second metal gate. A width of a top surface of the second gap-filling metal layer is equal to a width of a bottom surface of the second gap-filling metal layer.

According to one embodiment of the present disclosure, a method for forming a semiconductor is provided. The method includes following operations. A substrate including a first region and a second region is received. A first FET device is formed in the first region, and a second FET device is formed in the second region. A first gate trench is formed in the first FET device, and a second gate trench is formed in the second FET device. A first high-k dielectric layer is formed in the first gate trench, and a second high-k dielectric layer is formed in the second gate trench. A first work function metal layer is formed in the first gate trench, and a second work function metal layer is formed in the second gate trench. The first gate trench is filled with a first gap-filling metal layer, and the second gate trench is filled with a second gap-filling metal layer. A width of a top surface of the first gap-filling metal layer is greater than a width of a top surface of the second gap-filling metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first transistor comprising a first fin structure and a first metal gate over the first fin structure, wherein the first metal gate comprises a first work function metal layer and a first gap-filling metal layer; and
a second transistor comprising a second fin structure and a second metal gate over the second fin structure, wherein the second metal gate comprises a second work function metal layer and a second gap-filling metal layer,
wherein the first metal gate and the second metal gate provide a same work function, a width of the first metal gate is equal to a width of the second metal gate, and a width of a top surface of the first gap-filling metal layer is greater than a width of a top surface of the second gap-filling metal layer.

2. The semiconductor structure of claim 1, wherein the first gap-filling metal layer and the second gap-filling metal layer comprise a same material.

3. The semiconductor structure of claim 1, wherein the first work function metal layer and the second work function metal layer comprise a same material.

4. The semiconductor structure of claim 1, wherein the first work function metal layer and the second work function metal layer comprise a same thickness.

5. The semiconductor structure of claim 1, wherein a width of the first fin structure and a width of the second fin structure are equal.

6. The semiconductor structure of claim 1, further comprising:
a first intervening metal layer between the first work function metal layer and the first gap-filling metal layer; and
a second intervening metal layer between the second work function metal layer and the second gap-filling metal layer,
wherein the first intervening metal layer and the second intervening metal layer comprise a same material and a same thickness.

7. The semiconductor structure of claim 6, further comprising:
a first high-k dielectric layer in the first metal gate; and
a second high-k dielectric layer in the second metal gate,
wherein a portion of the first high-k dielectric layer is in contact with the first intervening metal layer, and the second high-k dielectric layer is separated from the second intervening metal layer.

8. The semiconductor structure of claim 7, further comprising:
a first metal layer between the first work function metal layer and the first high-k dielectric layer; and
a second metal layer between the second work function metal layer and the second high-k dielectric layer,
wherein the first metal layer and the second metal layer comprise a same material and a same thickness.

9. The semiconductor structure of claim 1, wherein a width of a bottom surface of the first gap-filling metal layer is less than the width of the top surface of the first gap-filling metal layer.

10. The semiconductor structure of claim 1, wherein a width of a bottom surface of the second gap-filling metal layer is equal to the width of the top surface of the second gap-filling metal layer.

11. A semiconductor structure comprising:
a radio frequency (RF) device comprising a first metal gate, wherein the first metal gate comprises a first gap-filling metal layer, and a width of a top surface of the first gap-filling metal layer is greater than a width of a bottom surface of the first gap-filling metal layer; and
a logic device comprising a second metal gate, wherein the second metal gate comprises a second gap-filling metal layer, and a width of a top surface of the second gap-filling metal layer is equal to a width of a bottom surface of the second gap-filling metal layer.

12. The semiconductor structure of claim 11, wherein the width of the bottom surface of the first gap-filling metal layer is equal to the width of the bottom surface of the second gap-filling metal layer.

13. The semiconductor structure of claim 11, wherein the first gap-filling metal layer and the second gap-filling metal layer comprise tungsten (W).

14. The semiconductor structure of claim 11, wherein the first metal gate further comprises a first high-k dielectric layer and a first intervening metal layer, wherein a first portion of the first intervening metal layer is in contact with the first high-k dielectric layer, and a second portion of the first intervening metal layer is in contact with a first work function metal layer.

15. The semiconductor structure of claim 11, wherein the second metal gate further comprises a second high-k dielectric layer and a second intervening metal layer, wherein the second intervening metal layer is separated from the second high-k dielectric layer by a second work function metal layer.

16. A method for forming a semiconductor structure, comprising:
receiving a substrate comprising a first region and a second region;
forming a first FET device in the first region and a second FET device in the second region;
forming a first gate trench in the first FET device and a second gate trench in the second FET device;
forming a first high-k dielectric layer in the first gate trench and a second high-k dielectric layer in the second gate trench;
forming a first work function metal layer in the first gate trench and a second work function metal layer in the second gate trench;
removing a portion of the first work function metal layer from the first gate trench; and
filling the first gate trench with a first gap-filling metal layer and filling the second gate trench with a second gap-filling metal layer,
wherein a width of a top surface of the first gap-filing metal layer is greater than a width of a top surface of the second gap-filling metal layer.

17. The method of claim 16, wherein the first work function metal layer and the second work function metal layer comprise a same material.

18. The method of claim 16, wherein the removing of the portion of the first work function metal layer further comprises:
forming a first sacrificial layer in the first gate trench in the first region, wherein a top surface of the first sacrificial layer is lower than an opening of the first gate trench;
forming a second sacrificial layer in the second region; and
removing the portion of the first work function metal layer exposed through the first sacrificial layer.

19. The method of claim 16, further comprising forming a first intervening metal layer in the first gate trench, wherein a portion of the first intervening metal layer is in contact with the first high-k dielectric layer, and a portion of the first intervening metal layer is in contact with a topmost portion of the first work function metal layer.

20. The method of claim 16, further comprising forming a second intervening metal layer in the second gate trench, wherein the second intervening metal layer is entirely separated from the second high-k dielectric layer.
